(19) United States
(12) Patent Application Publication
(10) Pub. No.: US 2015/0359111 A1
(43) Pub. Date: Dec. 10, 2015

(54) MEMORY DEVICE

(71) Applicant: KABUSHIKI KAISHA TOSHIBA, Minato-ku (JP)

(72) Inventor: Takeshi MITSUHASHI, Yokohama (JP)

(73) Assignee: KABUSHIKI KAISHA TOSHIBA, Minato-ku (JP)

(21) Appl. No.: 14/482,539

(22) Filed: Sep. 10, 2014

Related U.S. Application Data
(60) Provisional application No. 62/010,261, filed on Jun. 10, 2014.

(51) Int. Cl. H05K 5/00

(52) U.S. Cl. CPC H05K 5/003

(57) ABSTRACT

According to one embodiment, a memory device includes a device body including a terminal connectable to an external device, a memory, a controller configured to control the memory, and a plurality of concave portions, and a case including a plurality of convex portions which are capable of fitting into the plurality of concave portions in a state where a part of the device body is inserted into the case.

### CROSS-REFERENCE TO RELATED APPLICATIONS

This application claims the benefit of U.S. Provisional Application No. 62/010,261, filed Jun. 10, 2014, the entire contents of which are incorporated herein by reference.

### FIELD

Embodiments described herein relate generally to a memory device.

### BACKGROUND

Universal Serial Bus (USB) flash drives having a metal housing are known.

### BRIEF DESCRIPTION OF THE DRAWINGS

FIG. 1A is a top view showing a device body of a memory device according to a first embodiment;

FIG. 1B is a view along arrows 1B-1B of FIG. 1A;

FIG. 1C is a side view showing the device body of the memory device according to the first embodiment;

FIG. 2A is a top view showing a case of the memory device according to the first embodiment;

FIG. 2B is a view along arrows 2B-2B of FIG. 2A;

FIG. 2C is a view along arrows 2C-2C of FIG. 2A;

FIG. 2D is a side view showing the case of the memory device according to the first embodiment;

FIG. 2E is an illustration for explanation of projections shown in FIG. 2A;

FIG. 3 is a perspective view for explanation of a case for decoration according to the first embodiment;

FIG. 4A is a top view showing the memory device according to the first embodiment;

FIG. 4B is a view along arrows 4B-4B of FIG. 4A;

FIG. 4C is a view along arrows 4C-4C of FIG. 4A;

FIG. 4D is a side view showing a memory device according to a first embodiment;

FIG. 5A is a top view showing a device body of the memory device according to a second embodiment;

FIG. 5B is a view along arrows 5B-5B of FIG. 5A;

FIG. 5C is a side view showing the device body of the memory device according to the second embodiment;

FIG. 6A is a top view showing a case of the memory device according to the second embodiment;

FIG. 6B is a view along arrows 6B-6B of FIG. 6A;

FIG. 6C is a view along arrows 6C-6C of FIG. 6A;

FIG. 6D is a side view showing the case of the memory device according to the second embodiment;

FIG. 7A is a top view showing the memory device according to the second embodiment;

FIG. 7B is a view along arrows 7B-7B of FIG. 7A;

FIG. 7C is a view along arrows 7C-7C of FIG. 7A; and

FIG. 7D is a side view showing the memory device according to the second embodiment.

### DETAILED DESCRIPTION

In general, according to one embodiment, a memory device comprises: a device body comprising a terminal connectable to an external device, a memory, a controller configured to control the memory, and a plurality of concave portions; and a case comprising a plurality of convex portions which are capable of fitting into the plurality of concave portions in a state where a part of the device body is inserted into the case.

Embodiments will be described hereinafter with reference to the accompanying drawings.

In the following figures, portions corresponding to those of a preceding figure are given the identical numbers to those of the preceding figure, and the detailed explanation thereof will be omitted.

### First Embodiment

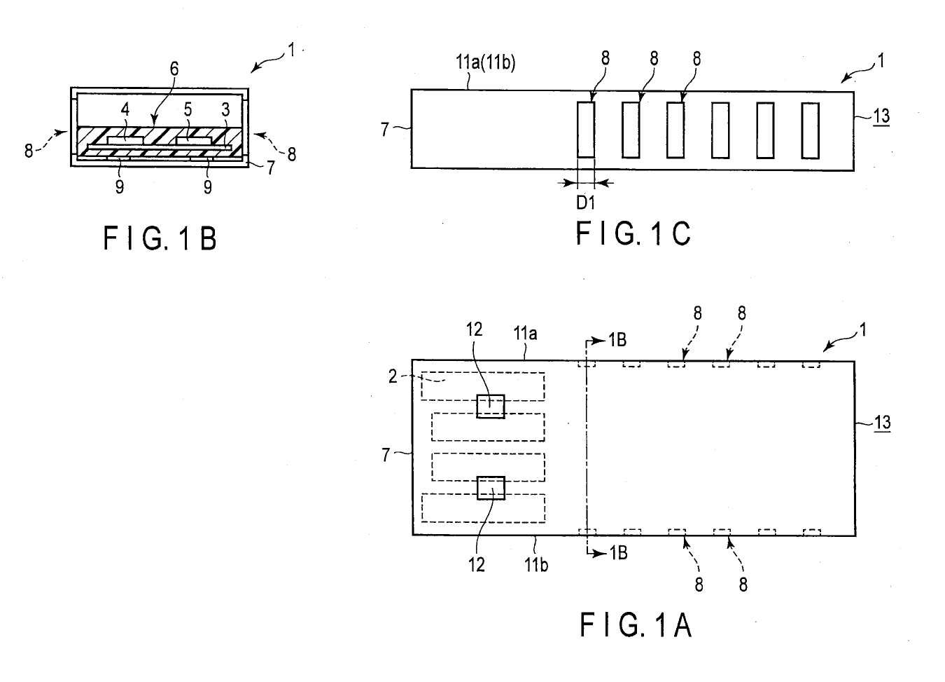

FIG. 1A is a top view showing a device body 1 of a memory device according to a first embodiment, FIG. 1B is a view along arrows 1B-1B of FIG. 1A, and FIG. 1C is a side view showing the device body 1 of the memory device according to the first embodiment. In the present embodiment, the memory device is a USB memory device.

In the figures, 1 represents the device body of the memory device according to the present embodiment, and the device body 1 comprises a USB terminal 2 connectable to a terminal of an external device, a substrate 3, a NAND flash memory 4, and a controller 5 configured to control the NAND flash memory 4. The USB terminal 2 is connected to one end side of the substrate 3, and the NAND flash memory 4 and the controller 5 are mounted on the substrate 3. That is, the device body 1 includes a structure (USB flash drive) which is inserted into a USB socket of a host apparatus and is electrically connected to the host apparatus.

In the present embodiment, the NAND flash memory 4 and the controller 5 are mounted on the substrate 3, for example, by a SiP. In FIG. 1B, the reference number 6 represents a SiP package including the substrate 3, the NAND flash memory 4 and the controller 5. The NAND flash memory 4 and the controller 5 may be mounted on the substrate 3 by other mounting techniques, not limited by a SiP.

Also, nonvolatile semiconductor memories other than the NAND flash memory 4 may be used. For example, a NOR-type nonvolatile semiconductor memory may be used. Moreover, instead of the NAND flash memory 4 (nonvolatile semiconductor memory), etc., other nonvolatile memories such as a nonvolatile magnetic memory (MRAM) may be used.

The device body 1 further comprises a housing 7 configured to house the USB terminal 2, the substrate 3, the NAND flash memory 4 and the controller 5. On the interior surface of the housing 7, a convex portion 9 processed in the shape of a convex is formed, and on the convex portion 9, a SiP package 6 is placed.

Material of the housing 7 is, for example, electrically conductive material such as metal, and the housing 7 has an electrical conductivity. The material of the housing 7 may be hard plastic or other insulating material.

The housing 7 comprises two side portions 11a and 11b facing each other, and each of the side portions 11a and 11b is provided with a plurality of concave portions 8. Here, in the present embodiment, the plurality of concave portions include holes which penetrate the side portions 11a and 11b of the housing 7.

The planar shapes of the plurality of concave portions 8 are, for example, rectangles. The widths D1 of openings of the plurality of concave portions 8 are short sides of the rectangles. However, the planar shapes of the plurality of concave portions 8 are not restricted to rectangles. In FIG. 1A, the reference number 12 represents holes provided on a top surface portion of the device body 1, and the reference number 13 represents an end portion opposite to the USB terminal 2.

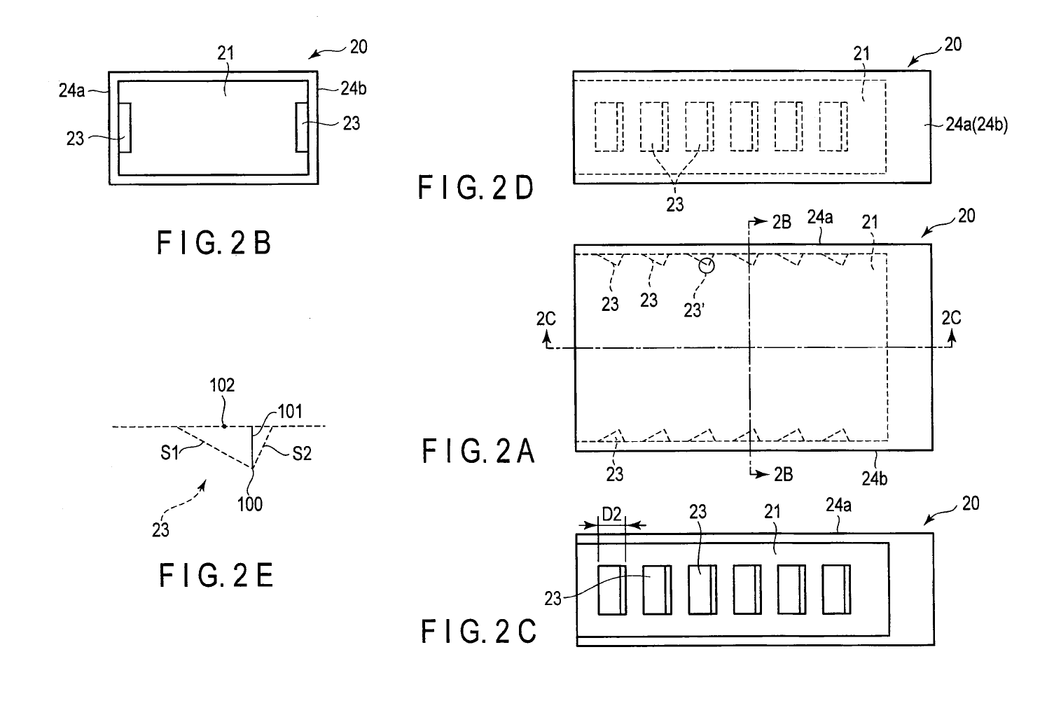

FIG. 2A is a top view showing a case 20 of the memory device according to the present embodiment, FIG. 2B is a view along arrows 2B-2B of FIG. 2A, FIG. 2C is a view along arrows 2C-2C of FIG. 2A, FIG. 2D is a side view showing the case 20 of the memory device according to the present embodiment, and FIG. 2E is an illustration for explanation of projections 23 of the case 20 of the memory device according to the present embodiment.

Into a space 21 surrounded by the case 20 of the memory device, a part of the device body 1 of the memory device is inserted. The part is, for example, an end portion opposite to the USB terminal 2. In this case, in a state where a part of the device body 1 is inserted into the case 20, a USB terminal side of the device body 1 projects outside the case 20.

The case 20 comprises the plurality of convex portions 23. In a state where a part of the device body 1 is inserted into the case 20, the plurality of convex portions 23 of the case 20 are fitted into the plurality of concave portions 8 of the device body 1 of FIG. 1A to FIG. 1C.

Here, the relationship between the plurality of concave portions 8 of the device body 1 of FIG. 1A to FIG. 1C and the plurality of convex portions 23 of the case 20 of FIG. 2A to FIG. 2E will be explained.

In the present embodiment, although the widths of tip portions 23′ of the plurality of convex portions 23 of the case 20 are smaller than the widths D1 of the openings of the plurality of concave portions 8 of the device body 1, the widths on the opposite sides to the tip portions 23′ of the plurality of convex portions 23 (widths of side portions 24a, 24b sides) are greater than the widths D1 of the openings of the plurality of the concave portions 8. That is, the shapes of the plurality of convex portions 23 taper toward the tip portions 23′.

In the present embodiment, the plurality of convex portions 23 each has the shape of an oblique cone. This oblique cone has, for example, as shown in FIG. 2E, a first inclined surface S1 on the entrance side of the space 21 and a second inclined surface S2 on the inner side of the space 21 in a direction in which a part of the device body 1 is inserted into the space 21.

In this case, a vertical line 101 drawn from an apex 100 of the oblique cone to the base does not accord with a centroid 102 of the base of the oblique cone. That is, the inclined surface S1 is longer than the inclined surface S2.

Also, the inclination of the first inclined surface S1 is more gradual than the inclination of the second inclined surface S2. The second inclined surface S2 may be a surface vertical to the base of the oblique cone, not an inclined surface.

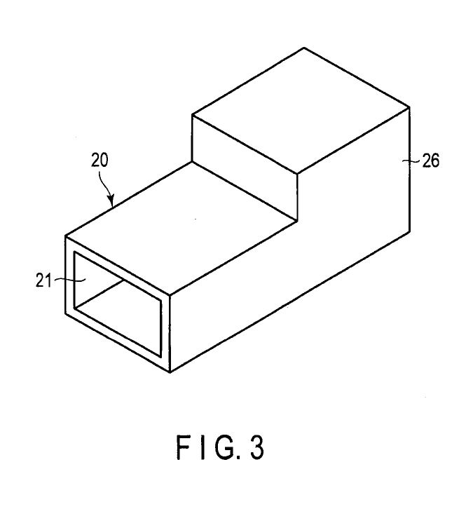

The case 20 comprises, for example, as shown in FIG. 3, a decorated solid portion 26. Material of the case 20 is, for example, plastic. In this case, the case 20 comprising the portion 26 can be formed, for example, by molding processing such as injection molding.

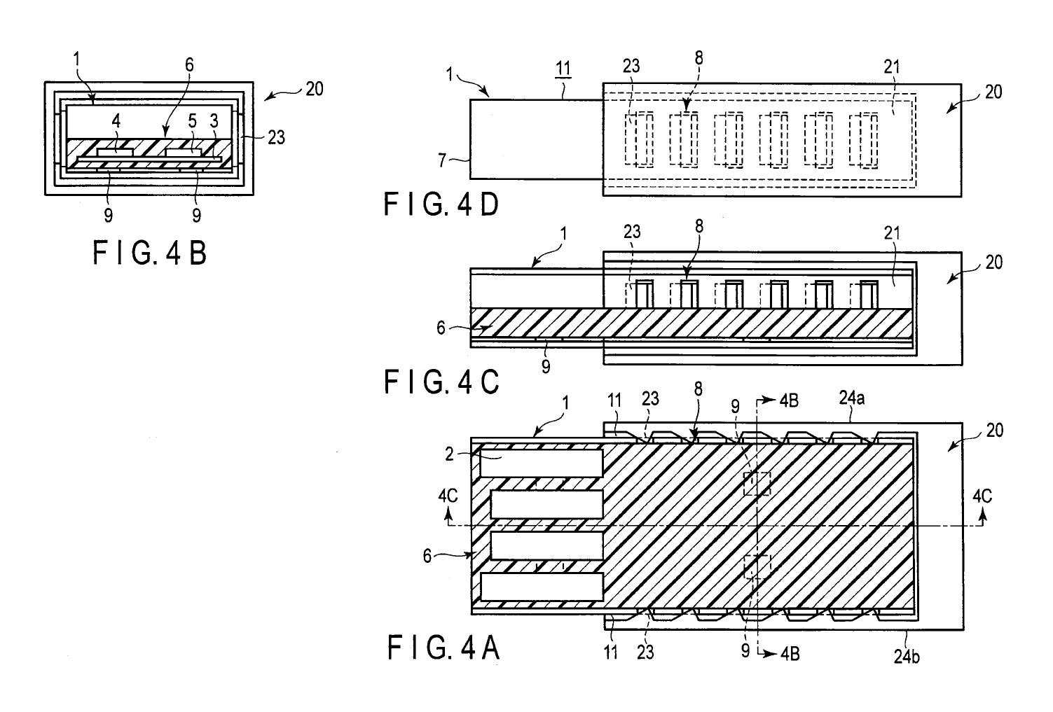

FIG. 4A is a top view showing the memory device according to the present embodiment, FIG. 4B is a view along arrows 4B-4B of FIG. 4A, FIG. 4C is a view along arrows 4C-4C of FIG. 4A, and FIG. 4D is a side view showing the memory device according to the present embodiment.

The memory device comprises the device body 1 and the case 20. A part of the device body 1 on the USB terminal 2 side projects outside from the case 20. When the device body 1 is inserted into the case 20, the plurality of convex portions 23 of the case 20 are inserted into the plurality of concave portions 8 of the device body 1.

As described above, the widths of the tip portions of the plurality of convex portions 23 of the device body 1 are smaller than the widths of the openings of the plurality of concave portions 8 of the case 20, however the widths on the opposite sides to the tip portions of the plurality of convex portions 23 (widths of side portions 24a, 24b sides) are greater than the widths of the openings of the plurality of concave portions 8 of the case 20. In addition, the plurality of convex portions 23 taper toward the tip portions. Thus, when the device body 1 is inserted into the case 20, the projections 23 are fitted into the holes 8, accordingly, the device body 1 is fixed in the case 20. That is, the device body 1 does not move in the case 20 needlessly.

Also, the inclination of the side surface S1 of each of the plurality of convex portions 23 shown in FIG. 2E is more gradual than the inclination of the side surface S2. Thus, as compared with a comparison example in which the inclination of the side surface S2 is more gradual than the inclination of the side surface S1, the plurality of convex portions 23 are more easily inserted into the plurality of concave portions 8, and the plurality of convex portions 23 are more hardly pulled out from the plurality of concave portions 8.

Thereby, bond strength between the device body 1 and the case 20 is secured, and the memory device with high mechanical strength can be realized.

### Second Embodiment

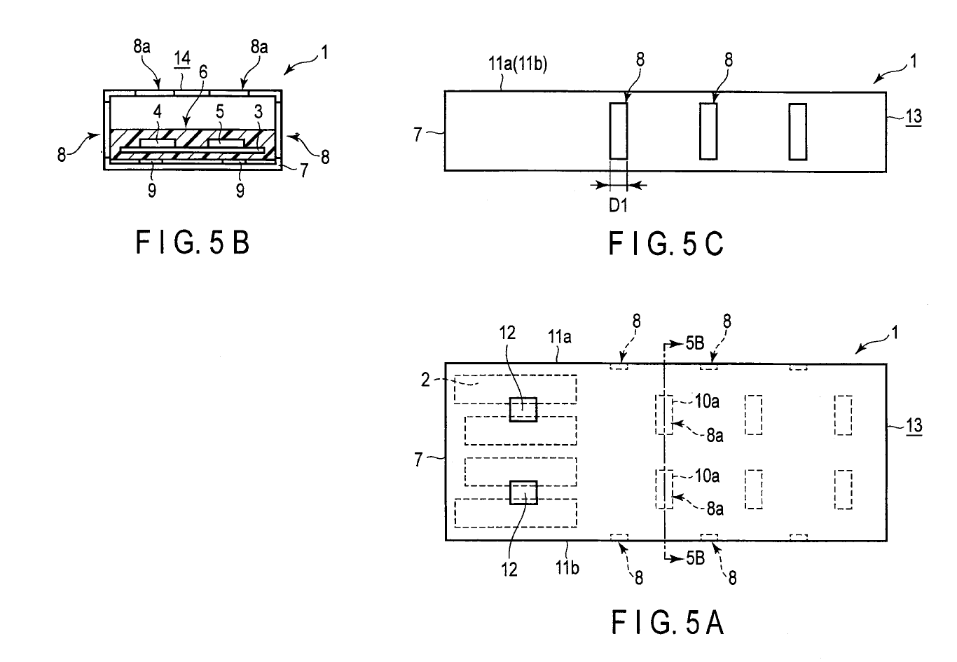

FIG. 5A to FIG. 5C are views showing the device body 1 of a memory device according to a second embodiment, and correspond to FIG. 1A to FIG. 1C of the first embodiment, respectively.

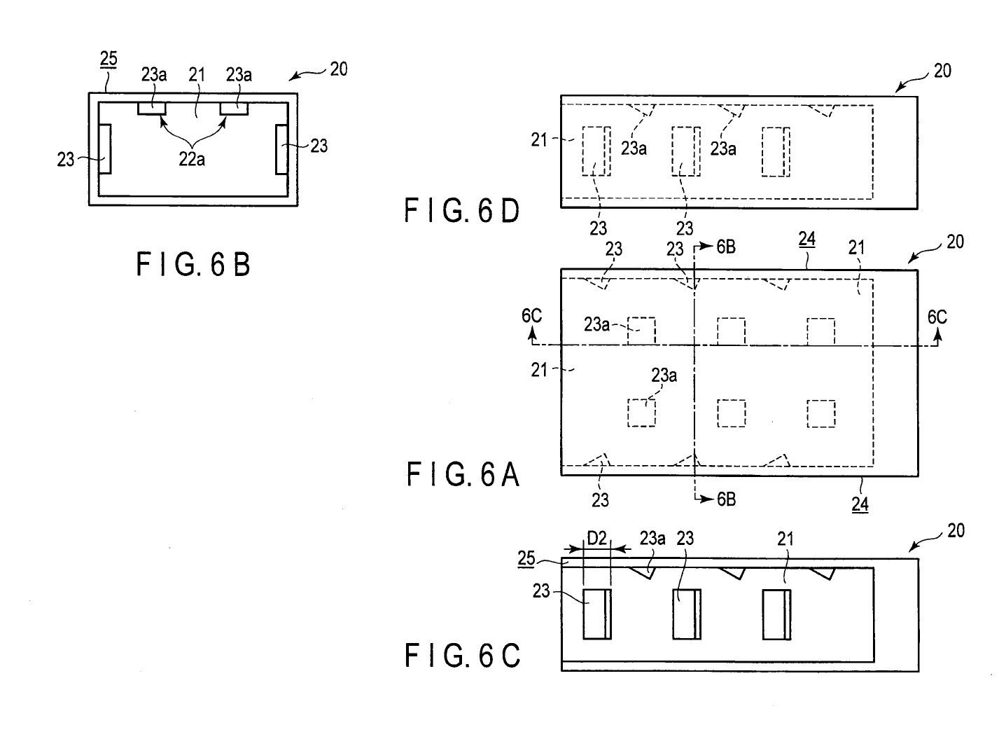

FIG. 6A to FIG. 6D are views showing a case of the memory device according to the second embodiment, and correspond to FIG. 2A to FIG. 2D of the first embodiment, respectively.

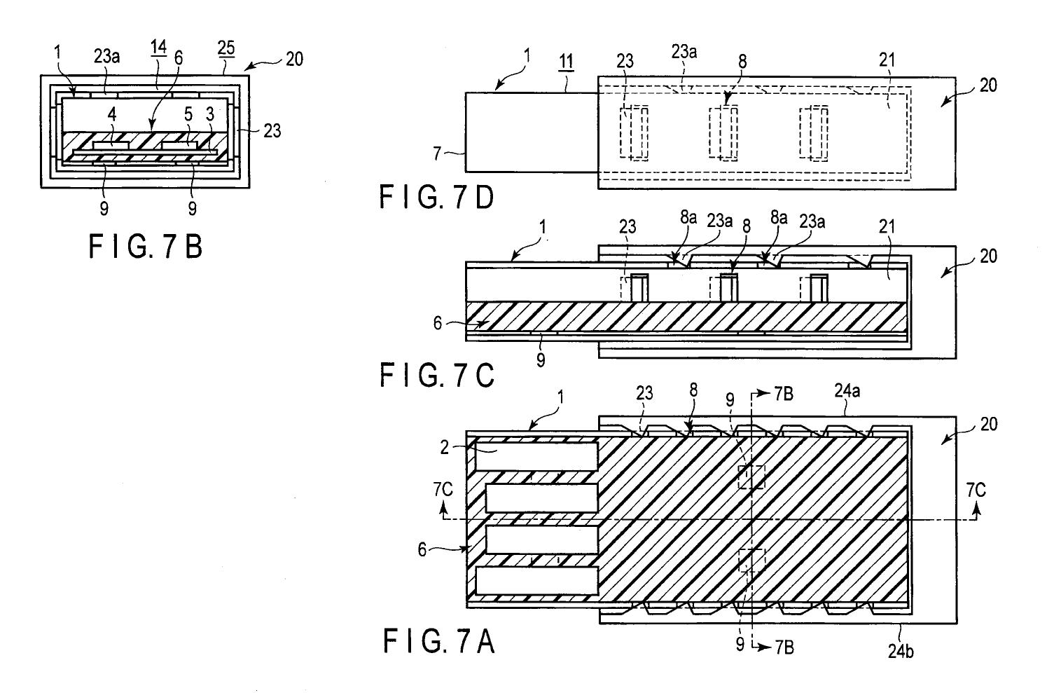

FIG. 7A to FIG. 7D are views showing the memory device according to the second embodiment, and correspond to FIG. 4A to FIG. 4D of the first embodiment, respectively.

The memory device of the present embodiment is provided with a plurality of concave portions 8a provided on a top surface portion 14 of the device body 1 and a plurality of convex portions 23a provided on a top surface portion 25 of the case 20, in addition to the plurality of concave portions 8 provided on the side portions 11a and 11b of the device body 1 and the plurality of convex portions 23 provided on the side portions 24a and 24b of the case 20.

Like this, the plurality of concave portions may be provided at a portion other than the side portions 11a and 11b of the device body 1, and similarly, the plurality of convex portions may be provided at a portion (in the present embodiment, a top surface portion) other than the side portions 24a and 24b of the case 20.

According to the present embodiment, the bond strength between the device body 1 and the case 20 is more increased, and thus, the memory device with high reliability can be realized.

Although the above description has been based on the premise that a memory device is the USB memory device, it can be applied to other memory devices.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory device comprising:
a device body including a terminal connectable to an external device, a memory, a controller configured to control the memory, and a plurality of concave portions; and
a case including a plurality of convex portions which are capable of fitting into the plurality of concave portions in a state where a part of the device body is inserted into the case.

2. The device of claim 1, wherein
the controller are in the housing, and the plurality of concave portions are provided on the housing.

3. The device of claim 2, wherein the plurality of concave portions are holes.

4. The device of claim 1, wherein at least one of the concave portions have a quadrilateral shape.

5. The device of claim 1, wherein a width of a tip portion of the convex portion is smaller than a width of an opening of the concave portion.

6. The device of claim 1, wherein a width of a first portion opposite to a tip portion of the convex portion is greater than a width of an opening of the concave portion.

7. The device of claim 1, wherein a width of the convex portion decrease toward tip portion of the convex portion.

8. The device of claim 1, wherein the plurality of convex portions each have a shape of oblique cone.

9. The device of claim 8, wherein the oblique cone comprises a first incline and a second incline in a direction in which a part of the device body is inserted into the case.

10. The device of claim 9, wherein
the first incline is an incline on an opening side of the case, and
the first incline is more gradual than the second incline.

11. The device of claim 9, wherein
the first incline is an incline on an opening side of the case, and
the first incline is longer than the second incline.

12. The device of claim 9, wherein the second incline is vertical to a base of the oblique cone.

13. The device of claim 2, wherein the terminal is provided on the housing and projects from the case.

14. The device of claim 1, wherein the device body comprises two side portions and a top surface portion, and the plurality of concave portions are provided on the side portions and on the top surface portion.

15. The device of claim 14, wherein the case comprises two side portions and a top surface portion, and the plurality of convex portions are provided on the side portions and on the top surface portion.
